(19) United States
(12) Patent Application Publication
(10) Pub. No.: US 2006/0091535 A1
(43) Pub. Date: May 4, 2006

(54) Fine pitch bonding pad layout and method of manufacturing same

(75) Inventors: Pei-Haw Tsao, Taichung (TW); Chao-Yuan Su, Koahsiung (TW); Chia Hsiung Hsu, Hsinchu City (TW); Chender Huang, Hsin-Chu (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., HSIN-CHU (TW)

(21) Appl. No.: 10/904,283

(22) Filed: Nov. 2, 2004

(51) Int. Cl. H01L 23/48; H01L 23/52

(52) U.S. Cl. 257/734; 257/773; 257/786

(57) ABSTRACT

Disclosed herein is a bonding pad formed on an IC chip for electrically coupling the IC chip to another device or component, and associated methods of manufacturing the bonding pad. In one embodiment, the bonding pad comprises a bonding portion having a bonding surface configured to receive an electrical connector. The bonding pad further comprises a probing portion having a probing surface adjacent and electrically coupled to the bonding surface, and configured to receive a probe tip for testing to the operation of the integrated circuit chip. In this embodiment, the bonding pad comprises a first planar dimension measured across the bonding portion and the adjacent probing portion, where the bonding portion further comprises a second planar dimension measured substantially perpendicular to the first planar dimension, and the probing portion comprises a third planar dimension measured substantially perpendicular to the first planar dimension and being less than the second planar dimension.

### TECHNICAL FIELD

Disclosed embodiments herein relate generally to bonding pads formed on substrates used in integrated circuit applications, and more particularly to increasing the number of bonding pads in the bonding layout, and thus decreasing the pitch of the bonding pads, on an IC chip without significantly affecting conventional manufacturing processes.

### BACKGROUND

The packaging of integrated circuit (IC) chips is one of the most important steps in the manufacturing process, contributing significantly to the overall cost, performance and reliability of the packaged chip. As semiconductor devices reach higher levels of integration, packaging technologies, such as chip bonding, have become critical. Packaging of the IC chip accounts for a considerable portion of the cost of producing the device and failure of the package leads to costly yield reduction.

As semiconductor device sizes have decreased, the density of devices on a chip has increased, along with the size of the chip, thereby making chip bonding more challenging. The bonding pads, such as those found on an IC chip, typically include both a bonding surface and a probing surface for contacting with a test probe. The probing surface is preferably separated, yet in electrical contact with, the bonding surface since marks caused by test probe tips may create problems with wirebond integrity if applied to bonding surfaces. In addition, as chip densities increase, also increased are the densities of wirebond or other type of electrical connections from the IC chips to the packages substrates. Due to the increased interconnect densities, the number of bonding pads needed on an IC chip, as well as a package substrate, is increased, yet package size is typically desired to be as small as possible. Thus, a finer or smaller “pitch” of the bonding pads is desired (i.e., a larger number of bonding pad versus a smaller number on the same size IC chip), so that package size may be kept small.

Unfortunately, as manufacturers attempt to decrease the pitch of bonding pads on IC chips, the typical approach is simply to decrease the size of each bonding pad so that more pads can be included on the IC chips. However, while this approach does decrease the size of the probing surfaces of the bonding pads with little or no impact to device performance, such an approach also results in a decrease of the size of the bonding surfaces. Such a decrease will affect package performance by affecting wirebond integrity and reliability due to a smaller contact area between the wire and the pad. Accordingly, what is needed is a technique for decreasing the pitch of the bonding pads on IC chips without detrimentally affecting overall package performance.

### SUMMARY

Disclosed herein is a bonding pad formed on an IC chip for electrically coupling the integrated circuit chip to another device or component. In one embodiment, the bonding pad comprises a bonding portion having a bonding surface configured to receive an electrical connector. The bonding pad further comprises a probing portion having a probing surface adjacent and electrically coupled to the bonding surface, and configured to receive a probe tip for testing to the operation of the IC chip. In this embodiment, the bonding pad comprises a first planar dimension measured across the bonding portion and the adjacent probing portion, where the bonding portion further comprises a second planar dimension measured substantially perpendicular to the first planar dimension, and the probing portion comprises a third planar dimension measured substantially perpendicular to the first planar dimension and being less than the second planar dimension.

In another aspect, disclosed is a method of manufacturing a bonding pad on an IC chip for electrically coupling the IC chip to another device or component. In one embodiment, the method comprises forming a bonding portion having a bonding surface configured to receive an electrical connector, where the bonding portion has a first planar dimension. The method further comprises forming a probing portion having a probing surface adjacent and electrically coupled to the bonding surface, and configured to receive a probe tip for testing to the operation of the IC chip. In such an embodiment, the probing portion has a second planar dimension substantially parallel to and less than the first planar dimension, wherein the bonding pad comprises a third planar dimension measured across the bonding portion and the adjacent probing portion and substantially perpendicular to the first and second planar dimensions.

In a further aspect, disclosed is a bonding pad layout formed on an IC chip for electrically coupling the IC chip to a package substrate. In one embodiment, the bonding pad layout comprises first and second bonding pads, where each bonding pad includes a bonding portion having a bonding surface configured to receive an electrical connector electrically coupled to the package substrate, and a probing portion having a probing surface adjacent and electrically coupled to the bonding surface, and configured to receive a probe tip for testing to the operation of the IC chip. In addition, in this embodiment, the bonding pad comprises a first planar dimension measured across the bonding portion and the adjacent probing portion, where the bonding portion comprises a second planar dimension measured substantially perpendicular to the first planar dimension. Furthermore, the probing portion comprises a third planar dimension measured substantially perpendicular to the first planar dimension and less than the second planar dimension. In this embodiment, the probing portion of the second bonding pad is adjacent to the bonding portion of the first bonding pad, and the probing portion of the first bonding pad is adjacent the bonding portion of the second bonding pad.

In yet another aspect, disclosed is a method of manufacturing a bonding pad layout on an IC chip for electrically coupling the IC chip to a package substrate. In one embodiment, the method comprises forming first and second bonding pads, wherein each such forming includes forming a bonding portion having a bonding surface configured to receive an electrical connector electrically coupled to the package substrate, where the bonding portion has a first planar dimension. Also included is forming a probing portion having a probing surface adjacent and electrically coupled to the bonding surface, and configured to receive a probe tip for testing to the operation of the IC chip. In such an embodiment, the probing portion has a second planar dimension substantially parallel to and less than the first planar dimension, wherein the bonding pad comprises a third planar dimension measured across the bonding portion and the adjacent probing portion and is substantially perpendicular to the first and second planar dimensions. In such a method, forming the first and second bonding pads further comprises forming the probing portion of the second bonding pad adjacent to the bonding portion of the first bonding pad, and forming the probing portion of the first bonding pad adjacent to the bonding portion of the second bonding pad.

### BRIEF DESCRIPTION OF THE DRAWINGS

For a more complete understanding of the principles disclosure herein, and the advantages thereof, reference is now made to the following descriptions taken in conjunction with the accompanying drawings, in which:

FIG. 1 illustrates a set of conventionally manufactured bonding pads;

FIG. 2 illustrates a set of bonding pads manufactured according to the principles disclosed herein; and

FIG. 3 illustrates a portion of a surface of an IC chip having several of the disclosed bonding pads formed thereon.

### DESCRIPTION OF THE EMBODIMENTS

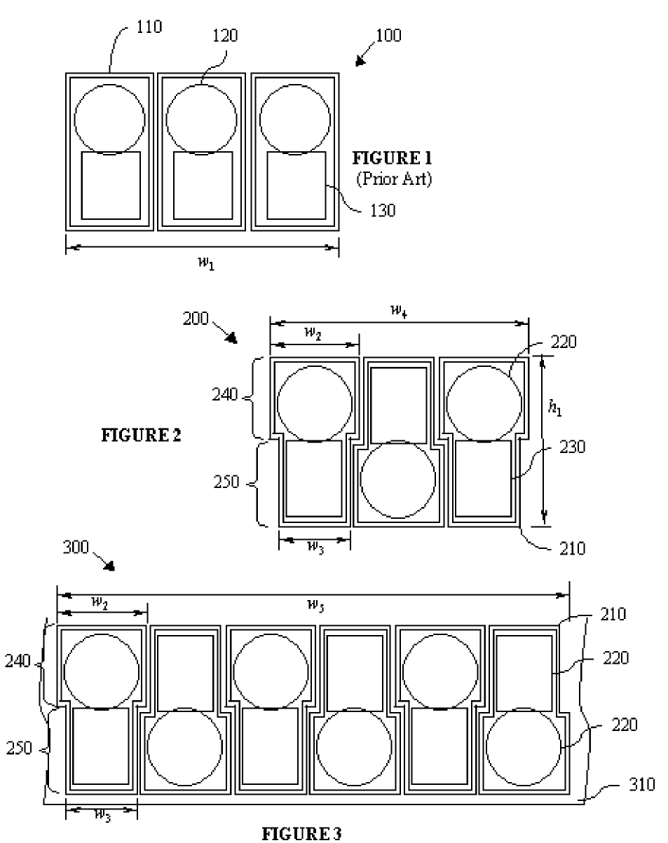

Referring initially to FIG. 1, illustrated is a set 100 of conventionally manufactured bonding pads (one of which is labeled 110). The bonding pads 110 each include a bonding surface (one of which is labeled 120), and a probing surface (one of which is labeled 130). In most applications, the bonding surfaces 120 and probing surfaces 130 have a small amount of overlap, as illustrated, so that an electrical connection between the two is present. Thus, as testing probes contact the probing surfaces 130, operational tests on the functionality of the IC chip connected to an IC package via the bonding surfaces 120 may be performed.

Since typical IC packages include IC chips having a number of input/output (I/O) terminals, a corresponding number of bonding pads 110 are usually formed on both the IC chip and the package substrate. Once packaged, the packaged may then be mounted and electrically connected to another structure, such as the printed circuit board (PCB) of an end product. The multiple bonding pads 110 formed on one side of the IC chip, usually at the periphery of the IC chip, each therefore have a collective planar dimension, width w₁. In addition, a minimum size for each bonding pad 110 is typically needed to assure connection integrity and performance. Thus, once the number of bonding pads 110 needed to interconnect the IC chip to the package substrate is determined, and a minimum size for each bonding pad 110 is chosen, the overall width w₁ of the set 100 of bonding pads 110 along one side of the IC chip is established. However, with the continued increases in IC chip densities, the continued push to decrease the size of electronic devices is difficult, if not impossible, to meet.

Turning now to FIG. 2, illustrated is a set 200 of bonding pads (one of which is labeled 210) manufactured according to the principles disclosed herein. As with conventional bonding pads, each of the disclosed bonding pads 210 includes a bonding surface (one of which is labeled 220) and a probing surface (one of which is labeled 230) for use in testing IC chip functionality, as well as for electrically connecting the IC chip to an IC package.

In one specific embodiment, the bonding surfaces 220 are each configured to receive an electrical connector, such as a solder ball employed in flip-chip interconnection techniques. In another embodiment, each of the bonding surfaces are configured to receive an electrical connector comprising a wirebond connection created through wirebonding techniques used to interconnect an IC chip to the substrate. In either of such embodiments, the bonding surfaces 220 may be configured to receive a metallurgical bond to accomplish both an electrical and mechanical bond on the bonding surfaces 220. Moreover, the bonding surfaces 220, as well as the probing surfaces 230, may be formed on the IC chip using an appropriate material that provides good electrical conduction in addition to promoting a strong metallurgical bond, such as nickel (Ni) or an alloy thereof.

The bonding pads 210 illustrated in FIG. 2, in accordance with the principles disclosed herein, differ from conventional bonding pads 110 in that the overall width w₂ of the set 200 of bonding pads 210 is less than the overall width w₁ of the conventional set 100 of bonding pads, even though the same number of bonding pads would be formed on the same IC chip. Specifically, the disclosed bonding pads 210 each include a bonding portion (one of which is labeled 240) and a probing portion (one of which is labeled 250). As shown, the bonding portions 240 are each configured to have a corresponding bonding surface 220 formed therein, while the probing portions 250 are each configured to have a corresponding probing surface 230 formed therein. These surfaces 220, 230 are comparable to those found in conventional bonding pads 110.

Also as illustrated in FIG. 2, each of the bonding pads 210 has another planar dimension, height h₁, measured across each bonding pad's bonding portion 240 and its adjacent probing portion 250. In one embodiment, the height h₁ of the bonding pads 210 disclosed herein is substantially equal to the height of conventional bonding pads, such as those illustrated in FIG. 1, such that the two types of pads are somewhat comparable. However, each of the bonding portions 240 of the disclosed bonding pads 210 further comprises another planar dimension, width w₂, measured across the bonding portion 240 and substantially perpendicular to the height h₁. Likewise, each of the probing portions 250 also comprises a further planar dimension, width w₃, measured across the probing portion 250 and substantially perpendicular to the height h₁; however, the width w₃ of each of the probing portions 250 is made less than the width w₂ of each of the bonding portions 240.

By forming the width w₃ of each probing portion 250 to be less than the width w₂ of each bonding portion 240, smaller probing surfaces 230 may be employed in each bonding pad 210, while the size of the bonding surfaces 220 can remain substantially equal to that found on conventional comparable bonding pads 110. As a result, each bonding pad 210 may be oriented 180 degrees to adjacent bonding pads 210 such that the probing portion 250 of one bonding pad 210 is adjacent the bonding portion 240 of an adjacent bonding pad 210, and the probing portion 250 of that first bonding pad 210 is adjacent to the bonding portion 240 of the second bonding pad 210. In an exemplary embodiment, the bonding and probing portions 240, 250 each comprise a square-shape, where the square-shape of the probing portion 250 is smaller than the square-shape of the bonding portion 240. Of course, any beneficial shape for the bonding and probing portions 240, 250 may also be employed, without limitation.

As illustrated, by forming the bonding pads 210 in this manner, the difference in widths w₂ and w₃ allows each bonding pad 210 to be interlocked or engaged with an adjacent bonding pad 210. Such 180-degree changes in orientation may then continue down the line of bonding pads 210 so that each one “interlocks” with an adjacent bonding pad 210. Therefore, the overall collective planar dimension, width w₄, of the set 200 of bonding pads 210 is less than the overall width w₁ of the conventional set 100 of bonding pads 110, even though the same number of bonding pads is employed, and the bonding and probing surfaces are substantially equal in size among both sets 110, 200.

Looking now at FIG. 3, illustrated is a portion 300 of one surface of an IC chip 310 having a layout of several of the disclosed bonding pads 210 formed thereon. In accordance with conventional practice, the IC chip 310 may be formed using traditional semiconductor manufacturing techniques. As discussed with reference to FIG. 2, each of the bonding pads 210 still includes a bonding surface 220 and a probing surface 230 formed in bonding and probing portions 240, 250, respectively, each with corresponding widths. As before, the width w₃ of each of the probing portions 250 is less than the width w₂ of each of the bonding portions 240 such that adjacent bonding pads 210 may be oriented to interlock, as described above.

As before, by forming the width w₃ of each probing portion 250 to be less than the width w₂ of each bonding portion 240, smaller probing surfaces 230 may be employed in each bonding pad 210, while the size of the bonding surfaces 220 can remain substantially equal to that found on comparable conventional bonding pads 110, so as to maintain bonding integrity when mounting and interconnecting the IC chip 310 to a package substrate or even directly to a PCB or other component. Accordingly, as discussed with reference to FIG. 2, the overall width w₅ of all of the bonding pads 210 formed on a side of the IC chip 310 is going to be less than a corresponding width of the same number of comparable conventional bonding pads 110 when the bonding and probing surfaces are substantially equal in size. This is because the same number of bonding pads 210 may be formed in a smaller space (or a larger number in an equal space), thus the “pitch” of the bonding pads becomes more fine than that found on conventional IC chips.

Therefore, as IC chip density is increased, and thus the number of needed bonding pads correspondingly increases, the disclosed technique allows a larger number of bonding pads 210 to be formed on the same size IC chip (and consequently on the package substrate) as the conventional approach by providing a finer pitch. Conversely, if only the same number of bonding pads is needed, the disclosed technique allows that same number of bonding pads to be formed on a smaller IC chip, thus decreasing the overall size of the finished IC package. Of course, as mentioned above, a decrease in IC package size can contribute to a decrease in the overall size of the finished product incorporating the IC package, as is typically desired. Moreover, since the bonding pads 210 resulting from the disclosed technique are composed of the same materials, substantially the same manufacturing processes (accounting for the change in pad orientation) may be employed. Therefore, little or no significant impact is made on current manufacturing equipment, materials, and processes by use of the disclosed technique. Additionally, the disclosed techniques for forming bonding pads is not limited to forming pads on IC chips, but may in fact be employed, as mentioned above, to form bonding pads on any component, including the package substrate itself.

While various embodiments of forming bonding pads on an IC chip according to the principles disclosed herein have been described above, it should be understood that they have been presented by way of example only, and not limitation. Thus, the breadth and scope of the invention(s) should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Brief Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

1. A bonding pad for electrically coupling an integrated circuit chip, the bonding pad comprising:
a bonding portion having a bonding surface configured to receive an electrical connector;
a probing portion having a probing surface adjacent and electrically coupled to the bonding surface, the probing portion configured to receive a probe tip for testing the operation of the integrated circuit chip; and
wherein the bonding pad includes a first planar dimension measured across the bonding portion and the adjacent probing portion, the bonding portion further comprising a second planar dimension measured substantially perpendicular to the first planar dimension, and the probing portion comprising a third planar dimension measured substantially perpendicular to the first planar dimension and substantially parallel to the second planar dimension, the third planar dimension being less than the second planar dimension.

2. The bonding pad according to claim 1, wherein the bonding surface is configured to receive an electrical connector comprising a solder ball.

3. The bonding pad according to claim 1, wherein the bonding surface is configured to receive an electrical connector comprising a wirebond.

4. The bonding pad according to claim 1, wherein the bonding surface is configured to receive a metallurgical bond.

5. The bonding pad according to claim 1, wherein the bonding and probing portions each comprise a square-shape, the square-shape of the probing portion being smaller than the square-shape of the bonding portion.

6. The bonding pad according to claim 1, wherein the bonding pad is formed on an integrated circuit chip electrically coupled to a package substrate via the bonding pad.

7-12. (canceled)

13. A bonding pad layout formed on an integrated circuit chip for coupling the integrated circuit chip to a package substrate, the bonding pad layout comprising:
first and second bonding pads, each bonding pad comprising:
a bonding portion having a bonding surface configured to receive an electrical connector electrically coupled to the package substrate,
a probing portion having a probing surface adjacent and electrically coupled to the bonding surface, and configured to receive a probe tip for testing the operation of the integrated circuit chip, and
wherein the bonding pad comprises a first planar dimension measured across the bonding portion and the adjacent probing portion, the bonding portion comprising a second planar dimension measured substantially perpendicular to the first planar dimension, and the probing portion comprising a third planar dimension measured substantially perpendicular to the fist planar dimension and being less than the second planar dimension; and
wherein the probing portion of the second bonding pad is adjacent the bonding portion of the first bonding pad, and the probing portion of the first bonding pad is adjacent the bonding portion of the second bonding pad.

14. The bonding pad layout according to claim 13, wherein each bonding surface is configured to receive an electrical connector comprising a solder ball.

15. The bonding pad layout according to claim 13, wherein each bonding surface is configured to receive an electrical connector comprising a wirebond.

16. The bonding pad layout according to claim 13, wherein each bonding surface is configured to receive a metallurgical bond.

17. The bonding pad layout according to claim 13, wherein each bonding and probing portion comprises a square-shape, the square-shapes of the probing portions being smaller than the square-shapes of the bonding portions.

18. The bonding pad layout according to claim 13, wherein the bonding portions of the first and second bonding pads are substantially the same size, and the probing portions of the first and second bonding pads are substantially the same size.

19. The bonding pad layout according to claim 13, wherein the package substrate also includes a bonding pad layout electrically coupled to the bonding pads on the integrated circuit chip.

20-26. (canceled)
